(19) United States
(12) Patent Application Publication
(10) Pub. No.: US 2026/0254365 A1
(43) Pub. Date: Aug. 27, 2026

(54) POWER UNIT

(71) Applicant: Delta Electronics (Shanghai) CO., LTD., Shanghai (CN)

(72) Inventors: Rui LI, Shanghai (CN); Weiyi FENG, Shanghai (CN); Yicong XIE, Shanghai (CN); Quanliang ZHANG, Shanghai (CN)

(73) Assignee: Delta Electronics (Shanghai) CO., LTD., Shanghai (CN)

(21) Appl. No.: 19/534,835

(22) Filed: Feb. 10, 2026

(30) Foreign Application Priority Data
Feb. 21, 2025 (CN) 2025102026220

(51) Int. Cl. H02M 7/00; H01F 3/14; H01F 27/32; H01F 27/36; H01F 38/14; H02M 7/797; H05K 7/14; H05K 7/20

(52) U.S. Cl. CPC H02M 7/003; H01F 3/14; H01F 27/324; H01F 27/36; H05K 7/14339; H05K 7/20909; H05K 7/20927; H01F 38/14; H02M 7/797

(57) ABSTRACT

A power unit includes: a transformer including a first winding and a second winding, the first winding being connected to a first voltage part, and the second winding being connected to a second voltage part, a voltage potential of the first voltage part being higher than the voltage potential of the second voltage part; and a first housing including an inner shielding layer, an insulating layer, and an outer shielding layer arranged sequentially from inside to outside, the insulating layer fully covering the first voltage part and the first winding, the inner shielding layer being at the same voltage potential as the first voltage part, and the outer shielding layer being grounded.

### CROSS REFERENCE

This application is based upon and claims priority to Chinese Patent Application No. 2025102026220, filed on Feb. 21, 2025, the disclosure of which is incorporated herein by reference in its entirety.

### TECHNICAL FIELD

The present disclosure relates to the field of power electronics technology, and more particularly to a power unit.

### BACKGROUND

A Solid-state transformer (SST) is a key node in a medium-voltage direct power supply architecture and is increasingly important as a core power supply device for electric vehicle charging, data center power supply, and high-energy-consuming DC industries. A power unit, the core of the SST, is key research and development object of various manufacturers. The power density of the SST power unit is a key metric for comparison among manufacturers. The power density of existing SST power units is relatively low, so it is necessary to design a new power unit structure to increase the power density, thereby enhancing product competitiveness.

### SUMMARY

According to an aspect of the present disclosure, a power unit is provided, including:

a transformer including a first winding and a second winding, the first winding being connected to a first voltage part, the second winding being connected to a second voltage part, and a voltage potential of the first voltage part being higher than a voltage potential of the second voltage part; and a first housing including an inner shielding layer, an insulating layer, and an outer shielding layer arranged sequentially from inside to outside, the insulating layer fully covering the first voltage part and the first winding, the inner shielding layer being at the same voltage potential as the first voltage part, and the outer shielding layer being grounded.

It should be understood that the above general description and the following detailed description are illustrative and explanatory only, and cannot limit the present disclosure.

### BRIEF DESCRIPTION OF THE DRAWINGS

The accompanying drawings, which are incorporated in and form a part of the specification, illustrate embodiments consistent with the present disclosure and, together with the description, serve to explain the principles of the present disclosure.

Obviously, the accompanying drawings described below are merely some embodiments of the present disclosure. Those skilled in the art can obtain other drawings based on these drawings without any creative effort.

FIG. 1 shows a schematic diagram of a topology of an SST power unit in an embodiment of the present disclosure;

FIG. 2 shows a schematic diagram of a position of an insulation and isolation interface of the SST power unit in the embodiment shown in FIG. 1;

FIG. 3 is a schematic diagram (cross-sectional view) of a high-voltage and low-voltage compartmentalized structure in a conventional SST power unit;

FIG. 4 shows a schematic diagram of a power unit according to an embodiment of the present disclosure;

FIG. 5 shows a schematic diagram of another power unit in an embodiment of the present disclosure;

FIG. 6 shows a schematic diagram of another power unit in an embodiment of the present disclosure;

FIG. 7 shows an experimental result diagram in an embodiment of the present disclosure;

FIG. 8 shows a schematic diagram of a voltage part arrangement position in an embodiment of the present disclosure;

FIG. 9 shows a schematic diagram of another power unit in an embodiment of the present disclosure;

FIG. 10 shows a schematic diagram of another power unit in an embodiment of the present disclosure;

FIG. 11 shows a schematic diagram of another power unit in an embodiment of the present disclosure;

FIG. 12 shows a schematic diagram of a position of a transformer in the embodiment shown in FIG. 11;

FIG. 13 shows a schematic diagram of another power unit in an embodiment of the present disclosure;

FIG. 14 shows a cross-sectional view along A-A in the embodiment shown in FIG. 13;

FIG. 15 shows a schematic diagram of another power unit in an embodiment of the present disclosure; and

FIG. 16 shows a schematic diagram of another power unit in an embodiment of the present disclosure.

### DETAILED DESCRIPTION

To make the objectives, technical solutions, and advantages of the embodiments of the present disclosure clearer, the technical solutions in the embodiments of the present disclosure will be clearly and completely described below with reference to the accompanying drawings. However, the illustrative embodiments can be implemented in many forms and should not be construed as being limited to the embodiments set forth herein; rather, these embodiments are provided so that the present disclosure will be comprehensive and complete, and the concept of the illustrative embodiments will be fully conveyed to those skilled in the art. The same reference numerals in the figures denote the same or similar structures, and therefore their detailed descriptions will be omitted.

When describing the elements/components/etc. described and/or illustrated herein, the terms “a”, “an”, “the”, “said”, and “at least one” are used to indicate the presence of one or more elements/components/etc. The terms “comprising”, “including”, and “having” are used to indicate an open-ended inclusion and to mean that additional elements/components/etc. other than the listed elements/components/etc. may exist. The terms “connected”, “joined”, and “butted” are used to indicate a direct connection between two elements/components or indirect connection between the two elements/components (i.e., presence of other elements/components between the two elements/components, such as, but not limited to, air). Furthermore, the terms “first”, “second”, etc., in the claims are used only as labels and are not intended to limit the number of objects to which they are applied.

Through research, the inventors found that for reinforced insulation between high-voltage and low-voltage modules of the conventional SST power unit structure, a large safety distance needs to be set at ends of high-voltage and low-voltage chambers, and the space required for setting this safety distance accounts for a large proportion of the volume of the entire power unit, resulting in a low power density of the power unit.

The present disclosure provides a power unit, which improves the power density of the power unit at least to a certain extent.

In the power unit provided in the embodiments of the present disclosure, a first housing is used to enclose a first voltage part and a first winding, that is, to enclose the high-voltage module and the high-voltage winding, the first housing includes an inner shielding layer, an insulating layer, and an outer shielding layer arranged sequentially from the inside to the outside, which can greatly reduce the safety distance required between the first voltage part and the second voltage part, reduce the length and volume of the power unit, and thus increase the power density of the power unit; by setting the inner shielding layer to be at the same voltage potential as the high-voltage side, the influence of the electromagnetic field generated by the high-voltage side on the low-voltage side can be reduced, thereby reducing electromagnetic interference, and the electric field distribution can also be homogenized, reducing the local concentration of electric field intensity, thereby reducing the thickness of the insulating layer and further improving the power density; the insulating layer can provide electrical isolation between the high-voltage side and the low-voltage side, prevent voltage breakdown, and ensure electrical safety; by grounding the outer shielding layer, any leaked current can be absorbed and conducted away, protecting the safety of the device and the user, which can further reduce the electromagnetic interference of the device to the outside world and improve electromagnetic compatibility.

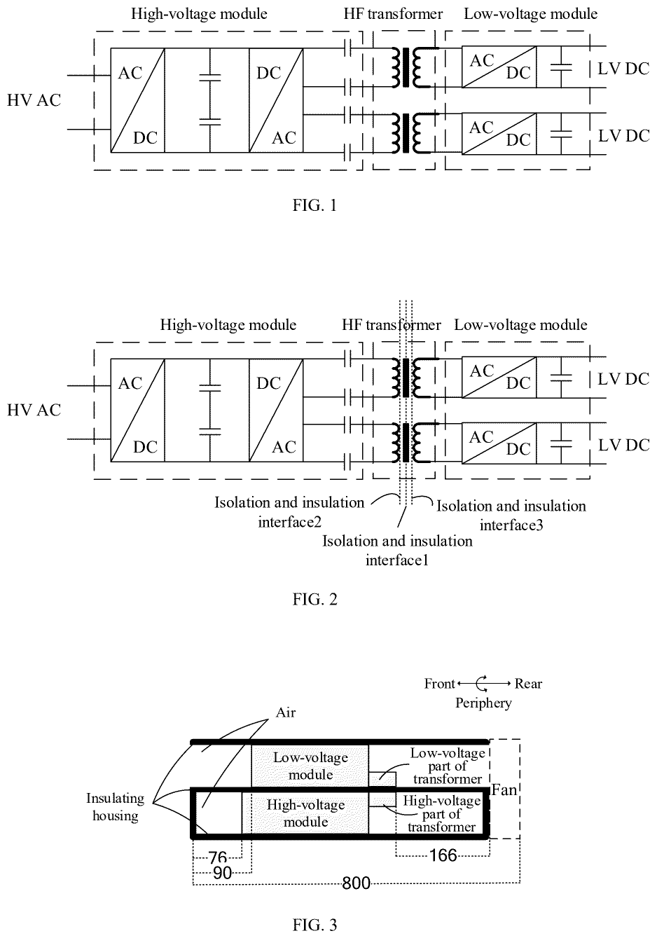

FIG. 1 shows a topology diagram of an SST (Solid State Transformer) power unit. The circuit of the SST power unit can be divided into three main parts: a high-voltage module, an HF (High Frequency) transformer, and a low-voltage module. The high-voltage module includes an AC/DC (AC to DC) rectifier circuit, a DC bus capacitor, and a DC/AC (i.e., a high-voltage part of DC to DC) circuit, etc.; the low-voltage module includes an AC/DC (i.e., a low-voltage part of DC to DC) circuit, a low-voltage output capacitor, etc. The SST can directly convert medium/high-voltage power frequency AC to low-voltage DC and has electrical isolation capabilities. Since a general transformer inherently has the electrical isolation capabilities (based on the principle of electromagnetic induction), the electrical isolation of the SST is generally achieved through an HF transformer.

The HF transformer inherently possess high-voltage and low-voltage electrical isolation capabilities, but proper insulation treatment is required between its high-voltage and low-voltage parts. As shown in FIG. 2, there are three types of isolation and insulation interfaces between its high-voltage and low-voltage parts:
Isolation and insulation interface 1: in the middle of the magnetic core, the magnetic core is divided into two halves, one half is at a high voltage potential and the other half is at a low voltage potential;
Isolation and insulation interface 2: between the high-voltage winding and the magnetic core, where the magnetic core is at a low voltage potential;
Isolation and insulation interface 3: between the low-voltage winding and the magnetic core, where the magnetic core is at a high voltage potential.

FIG. 3 shows a schematic diagram (cross-sectional view) of the high-voltage and low-voltage compartmentalized structure in a conventional SST power unit. In this power unit structure, the high-voltage module and the high-voltage part of the transformer are installed in an insulating cavity, which is an insulating housing made of insulating material. The high-voltage module and the high-voltage part of the transformer are partially enclosed by the insulating housing (only the periphery is insulated, and the front and rear are not covered), and there are ventilation holes at the front and rear for air cooling of the power unit. The high-voltage module and the low-voltage module share a fan module and each has an independent heat sink to cool their respective power devices.

The wall of the insulating housing between the high-voltage module and the low-voltage module is responsible for the main electrical insulation (10 kV to the ground). The insulating medium between the high-voltage module and the low-voltage module is the insulating housing and air, with the insulating housing being on the periphery, and the air being on the front and rear. Table 1 below shows the safety distance (electrical clearance) requirements in the solid-state transformer standard (IEC 62477). According to the solid-state transformer standard (IEC 62477), reinforced insulation is required between the high-voltage and low-voltage modules, as well as between the high-voltage components of the transformer and the fan. Therefore, a large safety distance (electrical clearance for reinforced insulation) must be left at the ends of the high-voltage and low-voltage compartments, and a large safety distance (electrical clearance for reinforced insulation) must also be left between the high-voltage components of the transformer and the fan. As shown in FIG. 3, the safety distance for air insulation between the high-voltage and low-voltage modules is (76+90) mm, i.e., 166 mm, which is greater than the safety distance of 160 mm in Table 1, and meets the requirements. The distance between the high-voltage part of the transformer and the fan module is 166 mm, which is greater than the safety distance of 160 mm in Table 1, and meets the requirements. Through calculation, it can be seen that the safety distance (76+166) mm in FIG. 3 accounts for about 30% of the length of the entire power unit of 800 mm, which means that the volume of the entire power unit is reduced by about 30%., which significantly reduces the power density of the power unit.

TABLE 1
IEC-62477

| | GND | Low-voltage side | Fan |
|---|---|---|---|
| High-voltage side | Basic insulation | Reinforced insulation | Reinforced insulation |
| 10 (kV) | distance 90 (mm) | distance 160 (mm) | distance 160 (mm) |

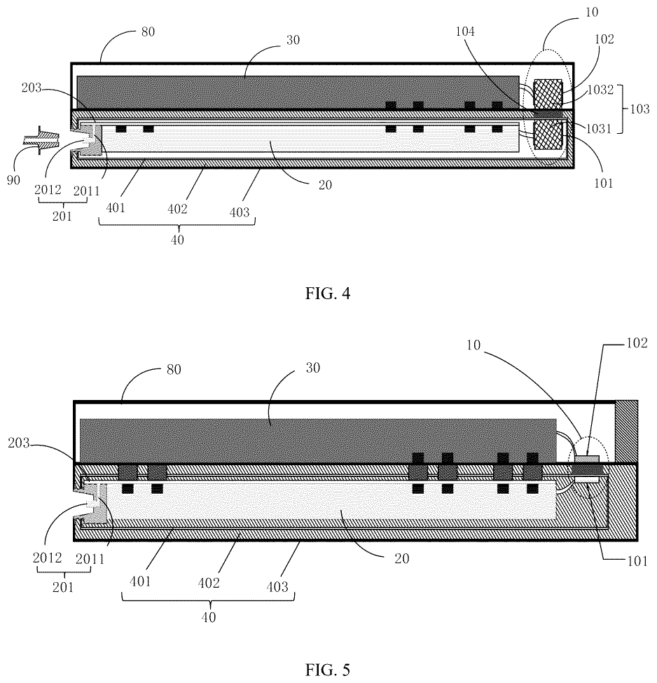

FIG. 4 shows a schematic diagram of a power unit according to an embodiment of the present disclosure. As shown in FIG. 4, the power unit provided in the embodiment of the present disclosure includes a transformer 10, a first voltage part 20, a second voltage part 30, and a first housing 40.

The transformer 10 includes a first winding 101, a second winding 102, and a magnetic core 103. The first winding 101 and the second winding 102 are wound on the magnetic core 103. The first winding 101 is connected to the first voltage part 20, and the second winding 102 is connected to the second voltage part 30. In the embodiment of the present disclosure, the voltage potential of the first voltage part 20 is higher than the voltage potential of the second voltage part 30. It should be noted that the voltage potential here can refer to a reference voltage potential relative to ground, that is, the first voltage part 20 can be the high-voltage module in the SST power unit shown in FIG. 1, and the second voltage part 30 can be the low-voltage module in the SST power unit shown in FIG. 1, so that the first winding 101 is a high-voltage winding, and the second winding 102 is a low-voltage winding. In some embodiments, the number of turns in the first winding 101 is greater than the number of turns in the second winding 102. In some other embodiments, the number of turns in the first winding 101 may be less than or equal to the number of turns in the second winding 102. Furthermore, in some embodiments of the present disclosure, as shown in FIG. 5, the magnetic core 103 may not be provided. FIG. 5 shows a schematic diagram of another power unit in an embodiment of the present disclosure, and in this embodiment, a coreless transformer is used, and the first winding 101 and the second winding 102 of the transformer 10 are arranged oppositely. The coreless structure is applicable not only to the structure where the first winding 101 is located within the inner shielding layer 401 of the first housing 40 and the second winding 102 is located outside the outer shielding layer 403 of the first housing 40, but also to the structure where both the first winding 101 and the second winding 102 are located within the inner shielding layer 401 of the first housing 40, with the second winding 102 passing through the first housing 40 and connected to the second voltage part 30. Since there is no magnetic core, this transformer has the advantages of simple structure, light weight, no noise, low cost, etc.

Please continue to refer to FIG. 4. In some embodiments, the magnetic core 103 includes a first magnetic core 1031 and a second magnetic core 1032. The first winding 101 is wound on the first magnetic core 1031, and the second winding 102 is wound on the second magnetic core 1032, and the first winding 101 and the second winding 102 are electrically connected to the first voltage part 20 and the second voltage part 30, respectively.

The first housing 40 includes an inner shielding layer 401, an insulating layer 402, and an outer shielding layer 403 arranged sequentially from the inside to the outside. The insulating layer 402 fully covers the first voltage part 20 and the first winding 101. The inner shielding layer 401 and the first voltage part 20 are at the same voltage potential, and the outer shielding layer 403 is grounded.

It should be noted that the aforementioned fully covering refers to the complete coverage of the insulating medium of the insulating layer 402 on top and bottom, left and right, and front and rear. It can be understood that on the basis that the insulating medium of the insulating layer 402 fully covers the first voltage part 20 and the first winding 101, in some embodiments, the inner shielding layer 401 and the outer shielding layer 403 also fully cover the first voltage part 20 and the first winding 101. Alternatively, at least one surface may not be covered by the inner shielding layer and/or the outer shielding layer, and the thickness of the insulating layer of the at least one surface not covered by the inner shielding layer and/or the outer shielding layer needs to be greater than the thickness of the insulating layer of other surfaces to compensate for the insulation strength. Furthermore, it should be noted that full coverage does not necessarily mean complete sealing. In some embodiments of the present disclosure, the inner and outer shielding layers may be provided with some through holes while meeting the electric field shielding requirements.

In some embodiments of the present disclosure, the second voltage part 30 is disposed outside the inner shielding layer 401. Furthermore, in the embodiment shown in FIG. 4, the isolation and insulation interface between the high voltage part and the low voltage part of the power unit is disposed in the middle of the magnetic core 103 (between the first magnetic core 1031 and the second magnetic core 1032), and the second voltage part 30 and the second winding 102 are disposed outside the outer shielding layer 403. Therefore, no winding passes through the inner shielding layer 401 and the outer shielding layer 403 of the first housing 40, which facilitates the sealing and insulation of the housing.

In the embodiment of the present disclosure, the insulating layer 402 of the first housing 40 is used to fully cover the first voltage part 20 and the first winding 101, that is, to cover the high-voltage module and the high-voltage winding, which can greatly reduce the safety distance required between the first voltage part 20 and the second voltage part 30, reduce the length and volume of the power unit, and thus increase the power density of the power unit; by setting the inner shielding layer 40 to be at the same voltage potential as the high-voltage side, the influence of the electromagnetic field generated by the high-voltage side on the low-voltage side can be reduced, thereby reducing electromagnetic interference, and the electric field distribution can also be homogenized, reducing the local concentration of electric field intensity can be reduced, thereby reducing the thickness of the insulating layer 402 and further improving the power density; by providing the insulating layer 402, it can provide electrical isolation between the high-voltage side and the low-voltage side, prevent voltage breakdown, and ensure electrical safety; and by grounding the outer shielding layer 403, any leaked current can be absorbed and conducted away, protecting the safety of the device and the user, which can also further reduce the electromagnetic interference of the device to the outside world and improve electromagnetic compatibility.

In some embodiments, as shown in FIG. 4, the first voltage part 20 is provided with a connection terminal 201, which is used to connect to a connection part 90 of an external device. The external device can be another power unit, a reactor, or the like. The connection part 90 may be integrally provided with the external device, or it may be one end of a connection cable, the other end of which is connected to the external device. After the connection terminal 201 is connected to the connection part 90 of the external device, a conductor in the connection terminal 201 is covered by an insulating medium, and the grounded shielding layer on the outer surface of the connection part 90 of the external device is electrically connected to the outer shielding layer 403. In some embodiments of the present disclosure, as shown in FIG. 4, the connection terminal 201 includes a first conductor 2011 and a second conductor 2012. The first conductor 2011 is connected to the first voltage part 20, and specifically, the first conductor 2011 can be connected to a Printed Circuit Board (PCB) 203 in the first voltage part 20. The first conductor 2011 is covered by the insulating medium of the first housing 40. After the second conductor 2012 is connected to the connection part of the external device, the second conductor 2012 is covered by the insulating medium in the connection part 90 of the external device. When the connection terminal 201 is mated with the connection part 90 of the external device, an insulation effect of solid insulation can be achieved. At this time, the safety distance from the connector conductor (second conductor 2012) of the connection terminal 201 to the low voltage (or ground) can be eliminated. In some embodiments of the present disclosure, the first conductor 2011 and the second conductor 2012 can be integrally provided. In some embodiments of the present disclosure, the connection terminal 201 is a male structure, the connection part 90 of the external device is a female structure, and the male structure and female structure can be a cable joint and a solid-encapsulated pole structure in a switchgear, which converts surface insulation into volume insulation. The connection terminal 201 and the connection part 90 of the external device installed and combined through the male-female connection, to form a continuous insulating medium covering or filling. The grounded shield layer on the outer surface of the connection part 90 of the external device can also be connected equipotentially with the grounded layer of the outer surface (outer shielding layer 403) of the module where the connection terminal 201 is located, forming a continuous shielding surface. Compared to air insulation, it reduces the impact on surrounding components and greatly improves insulation strength. In some other embodiments of the present disclosure, the connection terminal 201 can also be the female structure, and the connection part 90 of the external device can be the male structure.

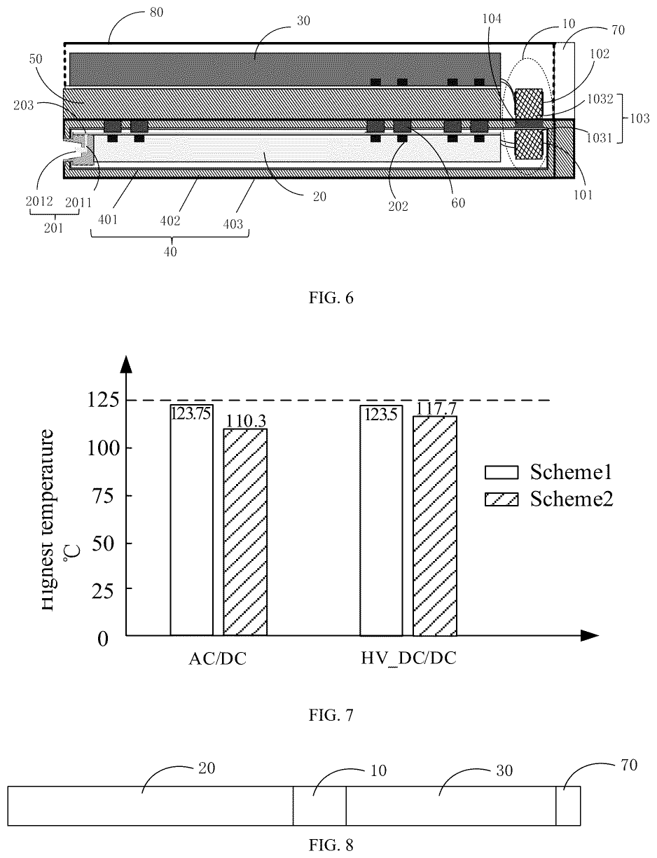

FIG. 6 shows a schematic diagram of another power unit in an embodiment of the present disclosure. In some embodiments, as shown in FIG. 6, the power unit further includes a heat sink 50. The second voltage part 30 is disposed outside the outer shielding layer 403, and the heat sink 50 is disposed adjacent to the outer shielding layer 403 and the second voltage part 30, and further, is disposed between the outer shielding layer 403 and the second voltage part 30. The heat sink 50 is used to dissipate heat from both the first voltage part 20 and the second voltage part 30, so as to reduce the number of heat dissipation system components, thereby saving the volume and cost of the power unit. In some other embodiments of the present disclosure, the heat sink 50 can also be replaced by a portion of the outer shielding layer 403 between the first voltage part 20 and the second voltage part 30, with the portion of the outer shielding layer 403 between the first voltage part 20 and the second voltage part 30 serving as a cold plate to dissipate heat from both the first voltage part 20 and the second voltage part 30.

In some embodiments, as shown in FIG. 6, the power unit further includes a heat conduction block 60, which is an insulating material and disposed within the insulating layer 402 of the first housing 40. The first voltage part 20 includes a power device 202, and the power device 202 may be disposed on the PCB 203. One end of the heat conduction block 60 passes through the inner shielding layer 401 and is thermally connected to the power device 202, that is, the heat conduction block 60 may directly contact the power device 202, or it may be thermally connected to the power device 202 indirectly via the PCB 203. When the power device 202 is disposed on the upper surface of the PCB 203, the power device 202 can directly contact the heat conduction block 60, and when the power device 202 is disposed on the lower surface of the PCB 203, the heat conduction block 60 can be thermally connected to the power device 202 via the PCB 203. The heat conduction block 60 is disposed corresponding to the power device 202 in the horizontal direction. High thermal conductivity material, such as a copper or ceramic block, can be provided in the corresponding position of the PCB where the power device 202 is connected to the heat conduction block 60, which allows the power device 202 to be thermally connected to the heat conduction block 60 through the high thermal conductivity material embedded in the PCB 203, further enhancing heat conduction and increasing heat dissipation capacity. The other end of the heat conduction block 60 contacts the outer shielding layer 403 or passes through the outer shielding layer 403 to contact the heat sink 50. In some embodiments, the projection of the heat conduction block 60 on the horizontal plane covers the projection of the power device 202 to which the heat conduction block 60 is thermally connected on the horizontal plane. That is, the area of the heat conduction block 60 on the horizontal plane is larger than the area of the power device 202 to which the heat conduction block 60 is thermally connected on the horizontal plane. The larger area of the heat conduction block 60 facilitates heat conduction and increases heat dissipation capacity. On this basis, in the case where the full coverage described in the present disclosure can also be provided with some through holes for components such as the heat conduction block 60 to pass through, provided that insulation conditions or electric field shielding requirements are met. When a heat sink 50 is disposed in the power unit, at least one heat transfer block having high thermal conductivity (not shown in the figure), such as a copper block, can also be disposed in the heat sink 50. The heat transfer block is disposed at the position corresponding to the power device 202 in the horizontal direction and is thermally connected to at least one power device 202 through the heat conduction block 60. In some embodiments, the projection of the heat transfer block on the horizontal plane covers the projection of the heat conduction block 60 which is in contact with the heat transfer block on the horizontal plane, which is conducive to increasing the heat dissipation area. The heat transfer blocks are in contact with the heat conduction block 60 respectively, which increases the heat dissipation efficiency.

In some embodiments, the heat conduction block 60 may be ceramic, such as an alumina ceramic sheet, an aluminum nitride ceramic sheet, or a boron nitride ceramic sheet. In some embodiments, the heat conduction block 60 may also be other thermally conductive and insulating materials such as diamond.

In the embodiment of the present disclosure, the power device 202 located in the first voltage part 20 is the main heat source in the SST power unit. Therefore, the heat of the power device 202 in the embodiment of the present disclosure is drawn out by a high thermal conductivity and insulating material (such as a ceramic sheet), which can dissipate the heat in a large power, thereby allowing the power of a single power device 202 to be increased, and thus increasing the power density of the power unit. By setting the heat conduction block 60 between the power device 202 and the outer shielding layer 403 where the heat conduction block 60 is a high thermal conductivity and insulating material (in some embodiments of the present disclosure, the thermal conductivity thereof is not less than 20 W/(mK) and the dielectric strength thereof is not less than 15 kV/mm), while meeting the insulation requirements, the heat of the power device 202 is drawn out by the thermal conductivity and insulating material to the external heat sink 50, thereby dissipating the heat of the device in a timely manner so as to meet the operating temperature requirements of the power device 202.

The SST power unit contains both medium/high-voltage AC and low-voltage DC, and thus proper insulation treatment is required. In the embodiment of the present disclosure, the insulating material of the insulating layer 402 needs to function as the main insulation (10 kV to ground), and the heat conduction block 60 (such as a ceramic sheet) between the power device 202 and the outer shielding layer 403 also needs to function as the main insulation.

The two-layer shielding (the inner shielding layer 401 and outer shielding layer 403) adopted in the embodiment of the present disclosure can reduce the thickness of the insulating medium of the insulating layer 402 between the inner shielding layer 401 and outer shielding layer 403, thereby reducing the volume of the first housing 40 and thus increasing the power density of the power unit.

In the embodiments of the present disclosure, heat dissipation simulation analysis for the heat conduction blocks 60 of different materials is also conducted, as detailed below:
Scheme 1: The power device 202 contacts the heat sink 50 via a 5 mm thick Al₂O₃ ceramic, where the copper block is embedded in part of the heat sink 50 as a heat transfer block, the copper block is thermally connected to the ceramic corresponding to the power device 202, and the projection of the copper block on the horizontal plane covers the projection of the ceramic contacting the copper block on the horizontal plane; and
Scheme 2: The power device 202 contacts the heat sink 50 via a 5 mm thick AlN ceramic, where no copper block is embedded in the heat sink 50.

The conditions are set as follows:
1. The first voltage part 20 is fully covered by the insulating layer 402, and the cavity where the first voltage part 20 is located is filled with fluorinated liquid (model: FC-40); (the fluorinated liquid is filled between the inner shielding layer 401 and the outer shielding layer 403, and between the inner shielding layer 401 and the first voltage part 20).
2. Loss settings: AC/DC (AC to DC, rectifier circuit, belonging to the first voltage part 20): 22.2 W/Mos; DC/DC high voltage part (DC to DC, DC conversion circuit): 22.0 W/Mos.

The simulation results are shown in FIG. 7. As can be seen from the results in FIG. 7, using the two thermally conductive and insulating materials mentioned above, the power device 202 in this structure meets the usage requirements (not exceeding 125° C., which is determined by the material of the circuit board).

The thermal conductivity of the alumina (Al₂O₃) ceramic is lower than that of the aluminum nitride (AlN), and by adding a copper block at the position in the heat sink corresponding to the alumina ceramic to increase heat diffusion, the heat dissipation performance can be enhanced to meet the requirements. Therefore, both the heat sink with aluminum oxide+local copper blocks and the heat sink with aluminum nitride and without copper block can meet the heat dissipation requirements for full insulation coverage.

In some embodiments, the positional relationship between the first voltage part 20 and the second voltage part 30 is in horizontal or vertical arrangement. For example, in FIGS. 4, 5 and 6, the first voltage part 20 and the second voltage part 30 can be stacked parallel to each other in the vertical direction. Furthermore, the first voltage part 20 and the second voltage part 30 can also be arranged in other positional relationships, such as horizontal arrangement in which the first voltage part 20 and the second voltage part 30 are on the same straight line as shown in FIG. 8. In some other embodiments of the present disclosure, the first voltage part 20 and the second voltage part 30 can also be arranged side-by-side and in parallel in the horizontal direction.

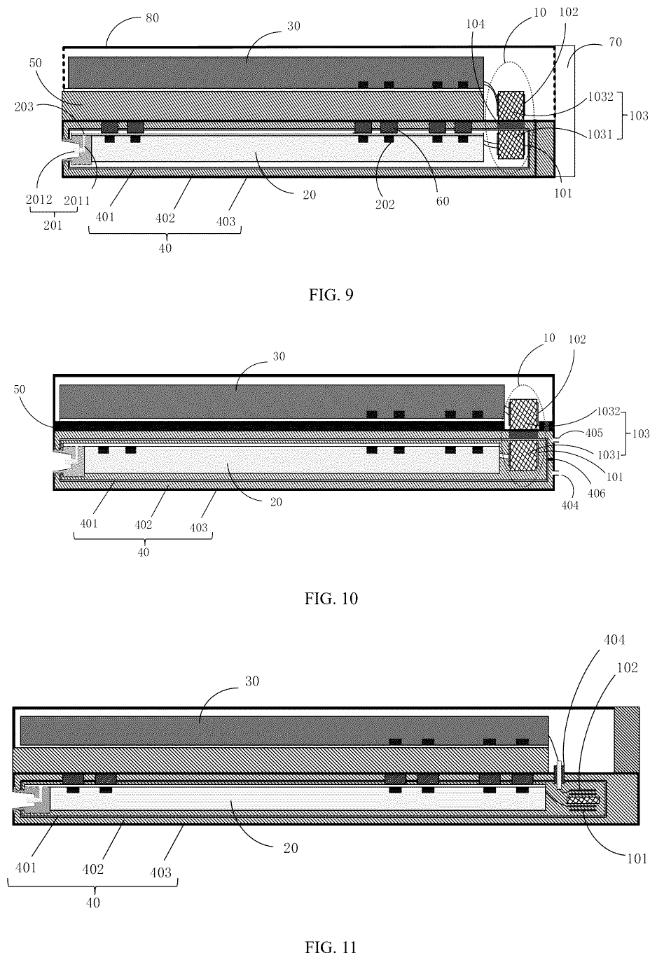

In some embodiments, as shown in FIG. 6, the power unit further includes a fan 70, which is disposed outside the outer shielding layer 403 and located at an end of the power unit for dissipating heat of the power unit. It is understood that the fan 70 can be disposed on one side of the second voltage part 30, i.e., above the first housing 40, as shown in FIG. 6. After the fan is started, the air blows towards the transformer 10 and the second voltage part 30. A second housing 80 can be disposed outside the second voltage part 30. The second housing 80 and the outer shielding layer 403 have the same voltage potential relative to ground, for example, both can be grounded. The second housing 80 at least covers the second voltage part 30, which can be used to protect the second voltage part 30. When used in conjunction with the fan 70, the second housing 80 can act as a wind deflector. In some embodiments of the present disclosure, as shown in FIG. 6, the front and rear sides of the second housing 80 can be provided as perforated plates to facilitate ventilation and heat dissipation. In some embodiments, the fan 70 can be disposed on one side of the transformer 10, as shown in FIG. 9, disposed outside the first housing, and arranged vertically along the first housing 40 and the second housing 80 in the height direction. After the fan 70 is started, the air blows towards the transformer 10, the first housing 40, and the second voltage part 30, thereby dissipating heat from the entire power unit. In addition, the fan 70 can also be disposed in other locations, which will not be described in detail in the embodiments of the present disclosure.

As shown in FIGS. 4, 5, 6, 9 and 10, the insulation and isolation interface can be located in the middle of the magnetic core. The magnetic core 103 includes a first magnetic core 1031 and a second magnetic core 1032. The first magnetic core 1031 is at a high voltage potential, and the second magnetic core 1032 is at a low voltage potential. The first winding 101 is wound on the first magnetic core 1031, and the second winding 102 is wound on the second magnetic core 1032, and the first winding 101 and the second winding 102 are electrically connected to the first voltage part 20 and the second voltage part 30, respectively. The first magnetic core 1031 and the first winding 101 are disposed inside the inner shielding layer 401, and the second magnetic core 1032 and the second winding 102 are disposed outside the outer shielding layer 403.

In some embodiments, the insulating layer 402 is insulating solid, and the outer shielding layer 403 and the inner shielding layer 401 can be one or a combination of more than one of: a non-perforated metal plate, a perforated metal plate, a metal coating, or a semi-conductive coating. The aperture size of the perforated metal plate is determined by the electric field shielding requirements. It should be noted that when the outer shielding layer is the perforated metal plate, the insulating medium of the insulating layer 402 needs to be insulating solid. Therefore, when the insulating layer 402 is insulating liquid or insulating gas, the outer shielding layer 403 is one or a combination of more than one of: a non-perforated metal plate, a metal coating, or a semi-conductive coating, where the metal coating or semi-conductive coating is applied on the surface of the solid insulating material. When the insulating medium of the insulating layer 402 is insulating liquid or insulating gas, the outer shielding layer 403 can be one or a combination of more than one of: a non-perforated metal plate, or a metal coating or semi-conductive coating applied on the insulating material housing (nylon, ABS, etc.). When the non-perforated metal plate is used, the heat sink can be directly welded onto it or the heat sink can be integrated with it. Furthermore, due to the good thermal conductivity of the metal, the heat dissipation efficiency of the unit can be improved. When the metal coating or semi-conductive coating on the insulating material housing (nylon, ABS, etc.) is used as the outer shielding layer, this housing can be manufactured by molding, which can greatly reduce costs and lighten the weight of the unit, facilitating installation and maintenance. The inner shielding layer 401 can also be at least partially provided as a perforated metal plate. When the inner shielding layer 401 is at least partially provided as the perforated metal plate, the insulating liquid or insulating gas can be disposed in the insulating layer 402 and between the inner shielding layer 401 and the first voltage part 20.

In some embodiments, the insulating layer 402 is insulating liquid. As shown in FIG. 10, the first housing 40 may also be provided with a liquid inlet 404 and a liquid outlet 405. The insulating liquid flows into the first housing from the liquid inlet 404 and flows out of the first housing 40 from the liquid outlet 405. In some embodiments, an insulating wall 406 may be provided on the shortest path from the liquid inlet 404 through the interior of the first housing 40 to the liquid outlet 405 to prevent the cooling liquid from flowing from the inlet to the outlet with the shortest distance on the right short side. In the embodiments of the present disclosure, the insulating liquid not only provides insulation but also heat dissipation. The insulating liquid is cooled by connecting to an external heat exchange device, thereby achieving heat dissipation. It can be understood that the position of the liquid inlet 404 can be lower than the position of the liquid outlet 405. For example, the liquid inlet 404 can be located at or near the bottom of the first housing 40, and the liquid outlet 405 can be located at or near the top of the first housing 40, which allows the insulating liquid to fill the space between the outer shielding layer 403 and the inner shielding layer 401, ensuring the insulation effect while implementing better heat dissipation. In some embodiments, the dielectric strength of the insulating liquid is not less than 10 kV/mm, and it has no flash point or a flash point not lower than 150 degrees Celsius, and has a boiling point not lower than 110 degrees Celsius.

In some embodiments, as shown in FIG. 4, the insulation and isolation interface is disposed in the middle of the magnetic core, and there is no insulating medium filled between the inner shielding layer 401 and the first voltage part 20 (high voltage module). In this embodiment, the high voltage module and the high voltage winding (i.e., the first voltage part 20 and the first winding 101) are completely enclosed in the first housing (insulated on the periphery and the front and rear); the insulation and isolation interface is disposed in the middle of the magnetic core, with part of the magnetic core being at high voltage potential and part being at low voltage potential. It can be understood that the heat sink can also be provided in this embodiment, and the position of the heat sink can be as shown in FIG. 6.

In addition, in the above embodiment, a heat conduction block 60 may be provided to dissipate heat of the power device 202, so that the above scheme is more suitable for scenarios where the heat generation of the high-voltage module is concentrated on the power device 202. In this embodiment, the heat conduction block 60 may adopt a ceramic sheet (such as AlN) or diamond with a relatively high thermal conductivity to export the heat generated by the power device 202, and no insulating medium needs to be filled in the inner shielding layer 401 (between the inner shielding layer 401 and the first voltage part 20). Similarly, in this embodiment, no winding passes through the inner shielding layer 401 and the outer shielding layer 403 of the first housing 40, which facilitates sealing and insulation treatment.

In the above embodiments, the second housing 80 may be or may not be provided outside the second voltage part 30. The second housing 80 can protect the second voltage part 30 and, when used in conjunction with the fan, the second housing 80 can act as a wind deflector to facilitate heat dissipation.

In some embodiments, the fan may also be provided in the embodiment of FIG. 4 to provide airflow that carries away the heat. The position of the fan may be as shown in FIG. 6, FIG. 8, FIG. 9 or FIG. 10.

In some embodiments, as shown in FIG. 10, the insulating medium is provided between the inner shielding layer 401 and the first voltage part 20. In some embodiments, the insulating medium between the inner shielding layer 401 and the first voltage part 20 can be insulating liquid. In some embodiments, the insulating medium between the inner shielding layer 401 and the first voltage part 20 can also be insulating solid or insulating gas. As can be seen from the above, when the insulating layer 402 is the insulating solid, regardless of whether the outer shielding layer 403 and the inner shielding layer 401 are provided with holes or not, the insulating medium between the inner shielding layer 401 and the first voltage part 20, such as fluid like the insulating liquid or insulating gas, will not leak to the outside of the first housing 40. Similarly, when the insulating layer 402 is the insulating liquid or insulating gas, the outer shielding layer 403 can be one or a combination of more than one of: a non-perforated metal plate, a metal coating, or a semi-conductive coating, and the inner shielding layer 401 can be one or a combination of more than one of: a perforated metal plate, a non-perforated metal plate, a metal coating, or a semi-conductive coating. In this case, the insulating medium between the inner shielding layer 401 and the first voltage part 20 will not leak to the outside of the first housing 40, either.

In some embodiments, the insulating medium between the inner shielding layer 401 and the first voltage part 20 may be silicone gel, insulating liquid, silicone rubber, or the like.

In the embodiments of the present disclosure, the insulating medium (insulating liquid, silicone gel, silicone rubber, etc.) is filled between the inner shielding layer 401 and the first voltage part 20, which facilitates heat conduction in the first housing 40, can improve temperature uniformity, and thus enhances reliability.

Meanwhile, since the first voltage part 20 is fully covered by the insulating medium within the inner shielding layer 401, the safety distance between devices on the PCB 203 of the first voltage part 20 changes from the safety distance for air insulation to the safety distance for solid insulation or liquid insulation (the dielectric strength of materials such as insulating liquid, silicone gel, and silicone rubber (approximately 18 kV/mm) is much greater than that of air (approximately 3 kV/mm), so the safety distance can be reduced. Taking a voltage of 1 kV as an example, the electrical clearance in air is 5.5 mm, while in fluorinated liquid, only 0.5 mm is sufficient), greatly reducing the safety distance and thus increasing the power density. Because the magnetic core 103 of the transformer 10 is divided into two parts, the first magnetic core 1031 and the second magnetic core 1032, there is only a magnetic path between these two parts, and there is no component (magnetic core or winding) passing through the first housing 40, which facilitates the insulation and sealing treatment of the first housing 40.

In some embodiments, the insulation and isolation interface is disposed in the middle of the magnetic core 103 (between the first magnetic core 1031 and the second magnetic core 1032). The first magnetic core 1031 and the first winding 101 of the transformer 10 are both disposed within the insulating medium between the inner shielding layer 401 and the first voltage part 20. The first magnetic core 1031 is at the high voltage potential, and the second magnetic core 1032 is at the low voltage potential. Both sides of the insulating material in the middle part of the magnetic core, i.e., both sides of the insulating material in the air gap part of the magnetic core, are coated with a semi-conductive coating to maintain the continuity of the inner and outer shielding layers. The insulating material in the air gap part can be, for example, one or a combination of more than one of: materials such as diamond, alumina, or aluminum nitride. The space between the inner shielding layer 401 and the outer shielding layer 403 is filled with insulating fluid, and the space between the inner shielding layer 403 (made of a mesh plate) and the first voltage part 20 is also filled with flowing insulating fluid, as shown in FIG. 10. The insulating fluid also serves as cooling liquid, flowing throughout the entire first housing 40. In this embodiment, the liquid inlet 404 and liquid outlet 405 of the insulating fluid can be directly welded onto the outer shielding layer 403 of the first housing 40, or can be connected to the first housing 40 via threads. The connection with an external insulating fluid pipeline can be in the form of a pagoda connector or a quick-connect connector, but is not limited to these. Optionally, the side of the outer shielding layer 403 located between the first voltage part 20 and the second voltage part 30 can be provided as a cold plate (heat sink 50) to dissipate heat of the second voltage part 30. The cooling medium in this cold plate can be separated from the insulating fluid in the first housing 40, each of which is provided with its own independent liquid inlet and outlet, allowing independent heat dissipation and reducing mutual heat interference. After being provided independently, since the second voltage part 30 is at a low voltage potential, the electrical insulation requirement for the cooling liquid passing through its heat sink 50 is low, and there is no need to use the insulating liquid with high cost, and industrial circulating water with low cost can be used, which significantly saves costs. Alternatively, the two cooling mediums can be communicated, allowing the cold plate and the housing to share the cooling insulating liquid, and share the liquid inlet and outlet, resulting in a simple structure.

In some embodiments of the present disclosure, the first voltage part 20 employs direct liquid cooling via insulating liquid circulation to improve heat dissipation efficiency, and the heat dissipation requirement can be met without providing a heat conduction block 60 between the power device 202 and the outer shielding layer 403. The first housing 40 is filled with the insulating liquid, improving the maintainability of the components within the first housing 40. Optionally, a heat sink is provided between the upper surface of the PCB corresponding to the power device and the inner shielding layer of the first housing 40 to increase the heat exchange area and improve the heat dissipation efficiency of the power device 202.

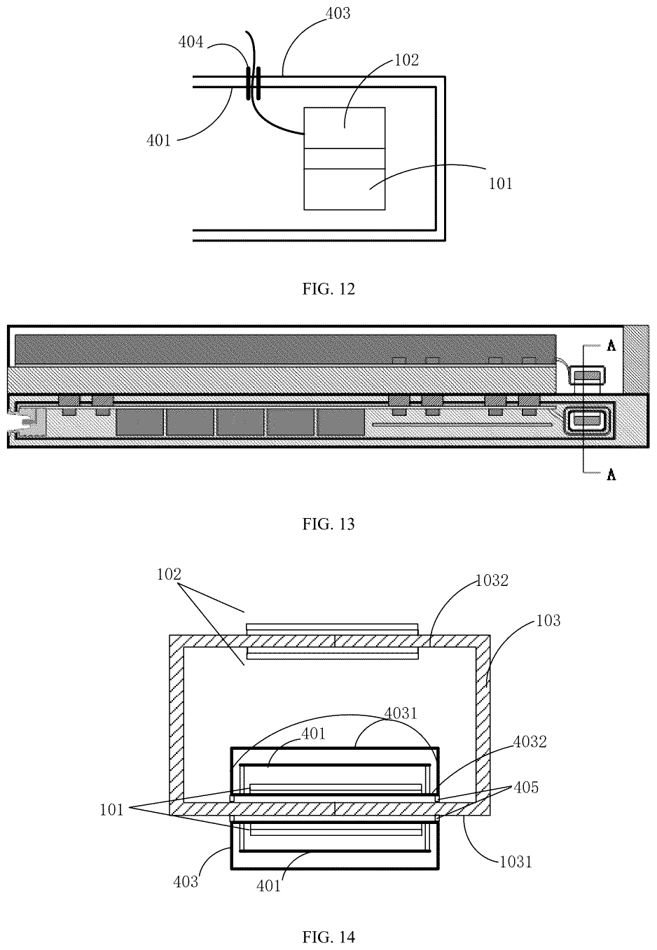

In some embodiments, FIG. 11 shows a schematic diagram of another power unit according to an embodiment of the present disclosure, and FIG. 12 shows the relationship between the transformer 10 and the inner shielding layer 401 in FIG. 11. The magnetic core of the transformer 10, as well as the first winding 101 and the second winding 102, can all be disposed within the insulating medium between the inner shielding layer 401 and the first voltage part 20. The power unit also includes two lead terminals 404 penetrating through the inner shielding layer 401 and the outer shielding layer 403, and the second winding 102 is connected to the second voltage part 30 via the two lead terminals 404. In some embodiments, the insulating medium between the inner shielding layer 401 and the first voltage part 20 can be insulating liquid, as shown in FIG. 11 and FIG. 12, in this case, the magnetic core is at a high voltage potential, and the insulating medium between the inner shielding layer 401 and the first voltage part 20 serves as an insulating and isolating medium, which is equivalent to providing an insulation and isolation interface between the second winding 102 and the magnetic core from the perspective of the electrical diagram.

The DC/DC conversion circuit has requirements for the relevant parameters of the transformer 10, such as magnetizing inductance, which mainly depends on the air gap of the magnetic core. In the above embodiments, since the entire transformer core is located within the inner shielding layer 401 of the first housing, the air gap is not affected by the thickness of the first housing 40 and can be adjusted according to actual needs to optimize the parameters of transformer 10 so as to achieve the optimal value required by the DC/DC conversion circuit.

In some embodiments, as shown in FIG. 4, the second winding 102 may also be disposed outside the outer shielding layer 403, the first winding 101 and the first magnetic core are disposed inside the inner shielding layer 401, an air gap is provided between the first magnetic core 1031 and the second magnetic core 1032, and the portion of the insulating layer 402 located in the air gap is provided with insulating material 104. The inner and outer surfaces of the insulating material 104 in the air gap portion are coated with a semi-conductive coating, the semi-conductive coating on the inner surface of the insulating material 104 in the air gap portion is connected to the inner shielding layer 401, and in some embodiments, the connection is a direct connection. The semi-conductive coating on the outer surface of the insulating material 104 in the air gap portion is connected to the outer shielding layer 403, and in some embodiments, the connection is a direct connection. When the inner shielding layer and the outer shielding layer are semi-conductive layers and the insulating layer 402 is solid, the semi-conductive layers serving as the inner and outer shielding layers can be continuously disposed on the inner and outer surfaces of the insulating material 104 in the air gap portion, and there is no need to coat the inner and outer surfaces of the insulating material 104 in the air gap portion with the semi-conductive coating.

In some embodiments, FIG. 13 shows a schematic diagram of another power unit according to an embodiment of the present disclosure, and FIG. 14 shows a cross-sectional view along A-A in the embodiment shown in FIG. 13. In the embodiments shown in FIG. 13 and FIG. 14, the insulation and isolation interface is provided between the first winding 101 and the magnetic core 103. The magnetic core 103 includes a first magnetic core 1031 and a second magnetic core 1032, the first winding 101 is wound on the first magnetic core 1031, and the second winding 102 is wound on the second magnetic core 1032. The outer shielding layer 403 includes a first outer shielding layer 4031 and a second outer shielding layer 4032 that are continuously disposed. The first outer shielding layer 4031 is disposed outside the inner shielding layer 401. The first housing 40 is provided with a hole 405 penetrating through the first outer shielding layer 4031 and the inner shielding layer 401, and the first magnetic core 1031 passes through the hole 405. The second outer shielding layer 4032 is disposed on the surface of the hole 405, and the second winding 102 and the magnetic core 103 are disposed outside the outer shielding layer 403. That is, the first winding 101 is disposed between the first outer shielding layer 4031 and the second outer shielding layer 4032, and the second winding 102 and the magnetic core 103 are not disposed between the first outer shielding layer 4031 and the second outer shielding layer 4032. To further illustrate the correspondence, in the schematic diagram shown in FIG. 14, the first outer shielding layer 4031 is shown as three sides of a rectangle, the second outer shielding layer is a side other than the three sides of the rectangle, and the second outer shielding layer 4032 surrounds the first magnetic core 1031. There is no second winding 102 or magnetic core 103 disposed between the first outer shielding layer 4031 and the second outer shielding layer 4032. In this case, the magnetic core 103 and the second winding 102 are at a low voltage potential, while the first voltage part 20 and the first winding 101 are at a high voltage potential. Similarly, in this embodiment, no winding passes through the inner and outer shielding layers of the first housing 40, facilitating sealing and insulation treatment. In this embodiment, the second winding 102 may also pass through the hole 405 and be wound on the first magnetic core 1031. That is, both the first winding 101 and the second winding 102 are wound on the first magnetic core 1031. When both the first winding 101 and the second winding 102 are wound on the first magnetic core 1031, the coupling between the two windings is high, the leakage magnetic flux is small, and the transformer efficiency is high.

In some embodiments, the portion of the insulating layer 402 located in the air gap between the first magnetic core 1031 and the second magnetic core 1032 is provided with an insulating material 104 (non-metallic material). The inner and outer surfaces of the insulating material 104 in the air gap portion are coated with a semi-conductive coating. The semi-conductive coating on the inner surface of the insulating material 104 in the air gap portion is connected to the inner shielding layer 401, and the semi-conductive coating on the outer surface of the insulating material 104 in the air gap portion is connected to the outer shielding layer 402. In some embodiments, the semi-conductive coating on the inner surface of the insulating material 104 in the air gap portion is directly connected to the inner shielding layer 401. The projection area of the insulating material 104 in the air gap portion on the upper surface of the first housing 40 is greater than or equal to the projection area of the magnetic core 103 on the upper surface of the first housing 40. Both sides of the insulating material 104 in the air gap portion are coated with the semi-conductive coating, and the semi-conductive coatings on the inner and outer surfaces of the air gap insulating material 104 are respectively connected to the inner shielding layer and the outer shielding layer of the housing through coating or other processes to maintain the continuity of the inner and outer shielding (the thickness of the semi-conductive layer is generally 10 μm to 200 μm, which is easy to achieve in process, and in some embodiments, the conductivity range is in 10⁻¹¹ s/m to 10³ s/m, where a lower conductivity can reduce losses, but it is not limited thereto.) The insulation performance of the insulating material 104 in the air gap portion can meet the main insulation requirements.

In some embodiments, the insulating material 104 in the air gap portion has good thermal conductivity, with a thermal conductivity coefficient ten times higher than that of other insulating materials in the first housing 40, which is conducive to exporting the heat of the first magnetic core 1031 (magnetic core of the high-voltage part) and allows the first magnetic core 1031 to operate at a suitable temperature. In some embodiments, the thickness of the insulating material in the middle of the magnetic core 103 (between the first magnetic core 1031 and the second magnetic core 1032) is thinner than the thickness of the insulating materials in other portions of the housing, which is conducive to improving the efficiency of the transformer 10. The insulating material 104 in the air gap portion has better insulating performance compared to other portions, and is a non-metallic material, which can reduce or eliminate eddy current losses, improve the efficiency of the transformer 10, and thus increase the power density of the power unit. The insulating material 104 in the air gap portion in the middle of the magnetic core 103 (between the first magnetic core 1031 and the second magnetic core 1032) can also be consistent with the insulating materials in other portions of the first housing 40, and is not separately provided. For example, it can be integrally formed with the insulating medium of the first housing 40 using the same material, and semi-conductive layers can be coated on the inner and outer sides of the insulating medium to form the inner shielding layer 401 and the outer shielding layer 403 of the first housing 40. When the inner and outer shielding layers are semi-conductive layers and the insulating layer 402 is solid, the semi-conductive layers serving as the inner and outer shielding layers can be continuously disposed on the inner and outer surfaces of the insulating material in the air gap portion, and there is no need to coat the inner and outer surfaces of the insulating material in the air gap portion with a semi-conductive coating.

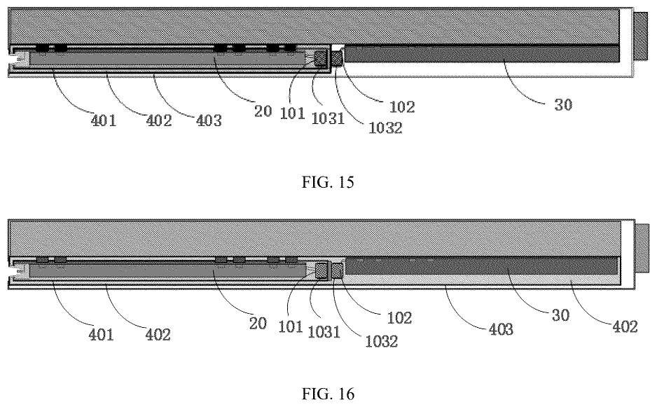

In some embodiments, FIG. 15 shows a schematic diagram of another power unit according to an embodiment of the present disclosure. The transformer 10 has a magnetic core including a first magnetic core 1031 and a second magnetic core 1032. The second winding 102 is wound on the second magnetic core 1032. The second magnetic core 1032, the second winding 102, and the second voltage part 30 can all be disposed outside the outer shielding layer 403. The first magnetic core 1031 is disposed inside the inner shielding layer 401, and the first winding 101 is wound on the first magnetic core 1031. The first voltage part 20 and the second voltage part 30 are horizontally arranged.

In some embodiments, as shown in FIG. 16, the second voltage part 30, the second magnetic core 1032, and the second winding 102 may be disposed outside the inner shielding layer 401 and inside the outer shielding layer 403. The first voltage part 20 and the second voltage part 30 may be horizontally arranged. The second voltage part 20 and the second magnetic core 1032 are embedded in the insulating layer 402. In some other embodiments of the present disclosure, the insulating layer 402 may be provided with a cavity, and the second voltage part 30 and the second magnetic core 1032 are disposed within the cavity.

As shown in FIG. 16, with the first voltage part 20 and the first winding 101 covered by the first housing, the second voltage part 30 can be covered by the outer shielding layer 403, the insulating layer 402 between the inner shielding layer 401 and the outer shielding layer 403 can be insulating liquid, and the second voltage part 30 is immersed in the insulating liquid. Compared to solid insulation, using the insulating liquid can prevent damage to the devices of the second voltage part 30. In some embodiments, the insulating layer 402 between the inner shielding layer 401 and the outer shielding layer 403 can also be solid insulation. The inner shielding layer 401 can contain insulating solid or insulating liquid, or is not provided with the insulating material (air insulation). The insulation and isolation interface is provided in the middle of the magnetic core. The heat sink is disposed adjacent to the outer shielding layer 403 and the second voltage part 30. Further, the heat sink is disposed on the same side of the outer shielding layer 403 and the second voltage part 30, such as the upper side. The common heat sink is provided on the outer shielding layer 403, and a fan assembly provides forced air cooling airflow. In the embodiment of the present disclosure, both the first voltage part 20 and the second voltage part 30 are wrapped by the insulating medium, providing a high level of protection, and are suitable for scenarios requiring high protection.

In the present disclosure, the term “and/or” is merely used for describing the associated relationship between the associated objects, indicating that three relationships can exist. For example, A and/or B can represent: A existing alone, A and B existing simultaneously, or B existing alone. Additionally, the character “/” here generally indicates that the related objects preceding and following the character is in an “or” relationship.

Other embodiments of the present disclosure will readily occur to those skilled in the art upon consideration of the specification and practice of the disclosure disclosed herein.

The present disclosure is intended to cover any variations, uses, or adaptations of the present disclosure that follow the general principles of the present disclosure and include common knowledge or conventional techniques in the art that are not disclosed herein. The description and examples are to be considered illustrative only, and the true scope and spirit of the present disclosure are indicated by the appended claims.

What is claimed is:

1. A power unit, comprising:
a transformer comprising a first winding and a second winding, wherein the first winding is connected to a first voltage part, the second winding is connected to a second voltage part, and a voltage potential of the first voltage part is higher than a voltage potential of the second voltage part; and
a first housing comprising an inner shielding layer, an insulating layer, and an outer shielding layer arranged sequentially from inside to outside, wherein the insulating layer fully covers the first voltage part and the first winding, the inner shielding layer and the first voltage part are at a same voltage potential, and the outer shielding layer is grounded.

2. The power unit according to claim 1, wherein the second voltage part is disposed outside the inner shielding layer.

3. The power unit according to claim 1, wherein the first voltage part is provided with a connection terminal, the connection terminal is configured for connecting to a connection part of an external device; and
in a case where the connection terminal is connected to the connection part of the external device, a conductor in the connection terminal is covered by an insulating medium, and a grounded shielding layer on an outer surface of the connection part of the external device is electrically connected to the outer shielding layer.

4. The power unit according to claim 3, wherein the conductor of the connection terminal comprises a first conductor and a second conductor, the first conductor is connected to the first voltage part and is covered by the insulating medium, and the second conductor is connected to the connection part of the external device and is covered by the insulating medium in the connection part of the external device.

5. The power unit according to claim 1, wherein the power unit further comprises a magnetic core, the magnetic core comprises a first magnetic core and a second magnetic core, the first winding is wound on the first magnetic core and the second winding is wound on the second magnetic core.

6. The power unit according to claim 5, wherein an air gap is provided between the first magnetic core and the second magnetic core, an insulating material is provided in a portion of the insulating layer located in the air gap, an inner surface and an outer surface of the insulating material of the portion in the air gap are each coated with a semi-conductive coating, the semi-conductive coating on the inner surface of the insulating material of the portion in the air gap is connected to the inner shielding layer, and the semi-conductive coating on the outer surface of the insulating material of the portion in the air gap is connected to the outer shielding layer.

7. The power unit according to claim 5, wherein the first magnetic core and the first winding are disposed within the inner shielding layer, and the second magnetic core and the second winding are disposed outside the outer shielding layer.

8. The power unit according to claim 1, wherein the power unit further comprises a magnetic core, the magnetic core comprises a first magnetic core and a second magnetic core, the outer shielding layer comprises a first outer shielding layer and a second outer shielding layer that are arranged continuously, the first outer shielding layer is disposed outside the inner shielding layer, the first housing is provided with a hole penetrating through the first outer shielding layer and the inner shielding layer, the first magnetic core passes through the hole, the second outer shielding layer is disposed on a surface of the hole, the second winding and the second magnetic core are disposed outside the outer shielding layer, the first winding is wound on the first magnetic core, and the second winding is wound on the first magnetic core or the second magnetic core.

9. The power unit according to claim 1, wherein an insulating medium is provided between the inner shielding layer and the first voltage part.

10. The power unit according to claim 9, wherein the power unit further comprises a magnetic core, the magnetic core, the first winding and the second winding are all disposed in the insulating medium between the inner shielding layer and the first voltage part, and wherein the power unit further comprises two lead terminals penetrating through the inner shielding layer and the outer shielding layer, and the second winding is connected to the second voltage part via the two lead terminals.

11. The power unit according to claim 9, wherein the insulating medium between the inner shielding layer and the first voltage part is insulating liquid, heat of the first voltage part is dissipated through the insulating liquid, the second voltage part is disposed outside the outer shielding layer, and a portion of the outer shielding layer disposed between the first voltage part and the second voltage part is a cold plate for dissipating heat of the second voltage part.

12. The power unit according to claim 5, wherein the second voltage part and the magnetic core are both disposed within the outer shielding layer, the first magnetic core is disposed within the inner shielding layer, and the second magnetic core is disposed outside the inner shielding layer; wherein the second voltage part and the second magnetic core are embedded in the insulating layer, or the insulating layer is provided with a cavity, and the second voltage part and the second magnetic core are disposed in the cavity.

13. The power unit according to claim 1, wherein the insulating layer is made of insulating liquid, the first housing is further provided with a liquid inlet and a liquid outlet, and the insulating liquid flows into the first housing from the liquid inlet and flows out of the first housing from the liquid outlet.

14. The power unit according to claim 1, wherein the power unit further comprises a heat conduction block, the heat conduction block is made of an insulating material; the first voltage unit comprises a power device; one end of the heat conduction block passes through the inner shielding layer and is thermally connected to the power device, and wherein projection of the heat conduction block on a horizontal plane covers projection of the power device to which the heat conduction block is thermally connected on the horizontal plane.

15. The power unit according to claim 14, wherein the heat conduction block is made of ceramic; wherein the power unit further comprises a heat sink, the second voltage part is disposed outside the outer shielding layer, and the heat sink is disposed adjacent to the outer shielding layer and the second voltage part.

16. The power unit according to claim 1, wherein the insulating layer is made of insulating solid, and the outer shielding layer and the inner shielding layer are one or a combination of more than one of: a non-perforated metal plate, a perforated metal plate, a metal coating, or a semi-conductive coating; or, wherein the insulating layer is made of insulating liquid or insulating gas, the outer shielding layer is one or a combination of more than one of: a non-perforated metal plate, a metal coating or a semi-conductive coating, and the inner shielding layer is one or a combination of more than one of: a perforated metal plate, a non-perforated metal plate, a metal coating or a semi-conductive coating.

17. The power unit according to claim 1, wherein the power unit further comprises a fan, the fan being disposed outside the outer shielding layer and located at an end of the power unit; or, wherein the power unit further comprises a second housing, the second housing and the outer shielding layer are at a same voltage potential, the second housing is disposed outside the outer shielding layer, and the second housing at least covers the second voltage part.

18. The power unit according to claim 1, wherein the first voltage part and the second voltage part are arranged horizontally or vertically.

19. The power unit according to claim 9, wherein the insulating medium between the inner shielding layer and the first voltage part is insulating solid.

20. The power unit according to claim 15, wherein the heat sink is further provided with a heat transfer block, the first voltage unit comprises a power device, the heat transfer block is thermally connected to the power device through the heat conduction block, and projection of the heat transfer block on the horizontal plane covers projection of the heat conduction block connected to the heat transfer block on the horizontal plane.
